(19) United States
(12) Patent Application Publication
(10) Pub. No.: US 2026/0081567 A1
(43) Pub. Date: Mar. 19, 2026

(54) DIGITALLY CONTROLLED EVEN HARMONIC DISTORTION CORRECTION

(71) Applicant: SKYWORKS SOLUTIONS, INC., Irvine, CA (US)

(72) Inventors: Mark R. Peting, Yamhill, OR (US); Eric Thomas King, San Jose, CA (US); Praveen Kumar Venkatachala, Portland, OR (US)

(21) Appl. No.: 19/326,074

(22) Filed: Sep. 11, 2025

Related U.S. Application Data
(60) Provisional application No. 63/693,856, filed on Sep. 12, 2024.

(51) Int. Cl. H03F 1/32

(52) U.S. Cl. CPC H03F 1/3247; H03F 1/3229

(57) ABSTRACT

A system for equalizing errors in common mode inputs due to mismatches, the system including a driver configured to provide a first voltage to a first bus and a second voltage to a second bus; a loop filter coupled to the first bus and to the second bus and configured to provide a feedback signal; a first current source configured to source or sink a constant current from the first bus and second bus; a second current source configured to source or sink a variable current from the first bus and second bus; and a controller configured to receive the feedback signal, based on the feedback signal, determine a first value for the variable current, and responsive to determining the first value, control the second current source to source or sink the variable current having the first value.

### CROSS-REFERENCE TO RELATED APPLICATIONS

This application claims priority under 35 U.S.C. § 119(e) to U.S. Provisional Patent Application No. 63/693,856, titled DIGITALLY CONTROLLED EVEN HARMONIC DISTORTION CORRECTION, filed on Sep. 12, 2024, which is hereby incorporated by reference in its entirety for all purposes.

### BACKGROUND

### 1. Field of the Disclosure

At least one example in accordance with the present disclosure relates generally to systems for compensating for common mode and differential mode errors in electronic systems.

### 2. Discussion of Related Art

Electronic signals may be mismatched in common mode operation due to process manufacturing mismatches, even when process elements have been closely matched. These mismatches may cause common mode operation to behave like differential mode operation.

### SUMMARY

According to at least one aspect of the present disclosure a system is presented for equalizing errors in common mode inputs due to mismatches, the system comprising: a driver configured to provide a first voltage to a first bus and a second voltage to a second bus; a loop filter coupled to the first bus and to the second bus and configured to provide a feedback signal; a first current source configured to source or sink a constant current from the first bus and second bus; a second current source configured to source or sink a variable current from the first bus and second bus; and a controller configured to receive the feedback signal, based on the feedback signal, determine a first value for the variable current, and responsive to determining the first value, control the second current source to source or sink the variable current having the first value.

In some examples, the controller is further configured to responsive to receiving the variable current and control the second current source to source or sink the variable current having the first value, receive a second feedback signal, responsive to receiving the second feedback signal, determine a second value of the variable current, and responsive to determining the second value, controlling the second current source to source or sink the variable current having the second value. In some examples, the system further comprises a third current source configured to source or sink the constant current from one of the first bus or second bus, wherein the first current source is configured to source or sink the constant current from the other of the first bus or second bus. In some examples, the system further comprises a third current source configured to source or sink the variable current from one of the first bus or second bus, wherein the second current source is configured to source or sink the variable current from the other of the first bus or second bus. In some examples, the system further comprises a load coupled between the first bus and the second bus. In some examples, the system further comprises a first resistor coupled along the first bus between the driver and the loop filter. In some examples, the system further comprises a second resistor coupled along the second bus between the driver and the loop filter. In some examples, the impedance of the first resistor is different than the impedance of the second resistor. In some examples, the controller is configured to determine a value of the variable current based on the difference between the impedance of the first resistor and the impedance of the second resistor. In some examples, the controller determines the value of the variable current to equalize the first voltage and the second voltage. In some examples, the system further comprises a third current source configured to source or sink the variable current from one of the first bus or the second bus, wherein the first second current source sources or sinks the variable current from the other of the first bus or second bus, and the controller includes one or more cells configured to drive the second current source and the third current source, wherein the controller uses a same subset of cells to drive the second current source and the third current source during a first time and a subsequent second time. In some examples, the controller drives the second current source during the first time and the third current source during the subsequent second time. In some examples, the first time is a first half-cycle of a clock cycle and the subsequent second time is the second half-cycle of the clock cycle. In some examples, the system further comprises a third current source coupled to the first bus and configured to source or sink an additional current from the first bus. In some examples, the driver is configured to operate in a current drive mode and a voltage drive mode. In some examples, the loop filter includes a first integrator having a first input coupled to a common mode voltage and a second input coupled to the first bus, and wherein the loop filter includes a second integrator having a third input coupled to the common mode voltage and a fourth input coupled to the second bus. In some examples, the loop filter includes a switch coupled to an output of the loop filter, a first impedance coupled between the first bus and the switch, and a second impedance coupled between the second bus and the switch. In some examples, the switch is configured to selectively couple the output of the loop filter to one of the first integrator or the second integrator at a given time.

According to at least one aspect of the present disclosure, a system is presented for equalizing errors in common mode inputs due to mismatches, the system comprising: a first bus configured to have a first voltage; a second bus configured to have a second voltage; a first delta-sigma modulator (DSM) having a first input coupled to the first bus, a second input coupled to the second bus, and an output coupled to an analog-to-digital converter (ADC); a second DSM having a first input coupled to the first bus, a second input coupled to the second bus, a third input coupled to the ADC, and an output coupled to the ADC; a dynamic-element-matching network (DEM) having a first input coupled to the ADC and a second input coupled to the ADC; and a digital-to-analog converter (DAC) having a first input coupled to the DEM and a second input coupled to the DEM, and a first output coupled to the first bus and a second output coupled to the second bus.

In some examples, the first DSM is configured to measure a first output signal of the DAC 414 and a second output signal of the DAC 414 and to provide a first feedback signal to the ADC; the second DSM is configured to measure the first output signal and the second output signal and to provide a second feedback signal to the ADC; the ADC is configured to receive the first feedback signal and the second feedback signal, and provide one or more control signals to the DEM; the DEM is configured to receive the one or more control signals and to determine one or more bit-cells of the DAC to drive; and the DAC is configured to output a first DAC output signal and a second DAC output signal based on the one or more bit-cells.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a first system for correcting common mode mismatches according to an example;

FIG. 2 illustrates a second system for correcting common mode mismatches according to an example;

FIG. 3 illustrates a third system for correcting common mode mismatches according to an example; and

FIG. 4 illustrate a fourth system for correcting common mode mismatches according to an example.

### DETAILED DESCRIPTION

As discussed below, embodiments herein relate to systems and methods for correcting harmonic distortions (e.g., even harmonic distortions) in electrical signals (such as audio signals). When generating common mode signals (for example, signals where the voltage and/or current is intended to be equal at two or more inputs to a device), resistor mismatches in the physical system can result in distortions and can cause the system to operate as though in a differential mode of operation. Even relatively small mismatches between resistors (e.g., 1% or less) can result in substantial distortions (e.g., 40 dB or less to 80 dB or more), and these distortions may be substantially greater than the system can tolerate (e.g., 10s, 100s, or 1000s of times greater).

One approach to correcting for resistor mismatch is to trim the resistors. However, even when trimming resistors, some mismatches may remain that can cause differential operation of the system. Furthermore, trimming resistors, and so forth, may require additional switches (e.g., transistors) that use power, occupy space on the chip, and require additional control mechanisms. Likewise, trimming resistors may reduce the linearity of the system.

Thus, even when using approaches like common mode feedback loops to correct for mismatch, trimming may be unable to provide a level of matching between resistors that is desired, and the feedback loop may be unable to reach input levels that are sufficiently constant and/or accurate.

Chopping is another approach used in common mode feedback loops to account for mismatches. However, chopping has many of the same issues as trimming resistors, and can add noise, often undesirable levels of noise, to the signal at relatively large voltages.

Systems and methods discussed herein may, in some examples, use the sinking of current (e.g., removing current) and/or sourcing of current (e.g., injecting current) into the system to correct for common mode mismatches. Control systems and/or drivers (for example, dynamic element matching networks (DEMs), digital-to-analog converters (DACs), and/or analog-to-digital converters (ADCs)) may also be configured to symmetrically control the current sources to ensure like behavior both during pulses and during static periods (e.g., when no pulse is being received or generated). For example, a DEM or DEM DAC may be configured to activate the same cells during both the pulse and static portions of the cycle (e.g., both halves of the cycle), thus ensuring that the current sources behave in a like manner.

In one example, the systems and methods discussed herein may source a constant or relatively constant common mode current (e.g., inject a relatively constant common mode current) into two or more inputs of a device or the system. In tandem or in sequence with the sourcing of the common mode current, other current sources may act as sinks to pull current away from the inputs. The sink current may be the same for all inputs, but may change over time (e.g., to account for drift in currents or voltages in the system as a whole caused by other factors, such as temperature).

In one example, the common mode and differential currents and/or voltages may be measured, and the behavior of the system adjusted to remove error components causing noise or distortion. In such examples, delta-sigma modulators (DSMs) or similar devices may be used to measure and/or predict the currents or voltages, and a DEM, DAC, and/or ADC may be controlled to ensure that the same cells are active during both the active and inactive portions of the cycle (where the active portion is when a pulse is being received, and the inactive portion is when no pulse is being received).

The above examples may be implemented separately or together, and will be discussed in greater detail below.

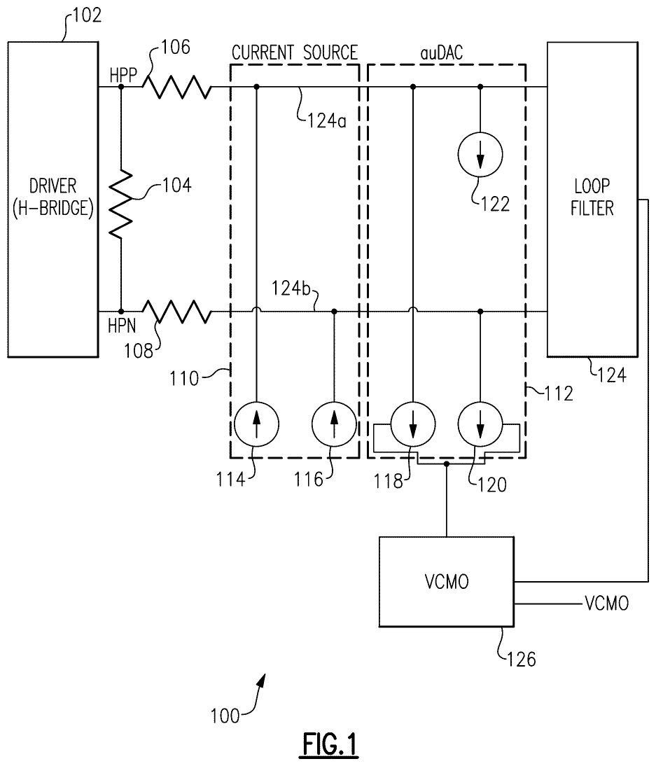

FIG. 1 illustrates a first system 100 (“system 100”) for correcting errors (e.g., distortion) in an electrical signal. The system 100 may correct errors due to mismatches in common mode operation (e.g., resistor mismatches or other mismatches) that cause the common mode inputs to be unequal. In some examples, the system 100 may correct errors when the difference between the common mode inputs exceeds a threshold difference.

The system 100 includes a driver 102, a load 104, a first resistor 106, a second resistor 108, a current source block 110, an audio DAC block 112 (“auDAC block 112”), a first current source 114 (“first current source 114”), a second current source 116, a third current source 118, a fourth current source 120, and a fifth current source 122, a loop filter 124, and a common mode voltage measuring circuit 126 (“VCMO 126”). Also shown are a first bus 124a and a second bus 124b.

In some examples, the system 100 may be used to produce an audible output signal (e.g., the load 104 may be a speaker or similar device). In some examples, the driver 102 generates a differential output signal to drive the audio signal produced by the load 104. For example, the HPP and HPN nodes may have different voltages and/or polarities from one another.

In some examples, the loop filter 124 may be used as part of a feedback loop to correct, adjust, or otherwise process the differential signal provided by the driver 102. For example, the loop filter 124 may be used as part of a feedback loop that removes noise and/or distortions from the differential signal 102 produced by the driver 102.

Protection circuitry, and/or other circuitry, may be connected to the system 100. These circuits may produce a common mode voltage on the first bus 124a and second bus 124b. The common mode voltage may have any amplitude, but may be relatively large compared to the expected common mode voltage the loop filter 124 is designed to handle.

For example, the loop filter 124, due to various constraints placed on the loop filter 124 (e.g., relating to size, efficiency, power consumption, the types of signals the loop filter 124 is expected to handle, and so forth) may not be equipped to handle large common mode voltages. Large common mode voltages may cause improper processing and/or improper correction of the driver's 102 differential signals as part of the feedback loop. In some examples, large common mode voltages may interfere with the operation of the loop filter 124 in other ways.

The various current sources 114, 116, 118, 120, 122 may be designed to source or sink current so as to control the common mode signal on the busses 124a, 124b. In some examples, the current sources 114, 116, 118, 120, 122 may be configured to reduce (or increase) the common mode signal created by the protection circuitry to zero or to some other desired value.

However, the currents generated by the current sources 114, 116, 118, 120, 122 may introduce a differential component on the busses 124a, 124b due to the resistor mismatch between the first resistor 106 and second resistor 108 (the resistor mismatch being the difference between the resistances of the two resistors 106, 108—this mismatch is usually due to physical variation in manufacturing processes that make it difficult or impossible to manufacture two resistors with exactly the same resistance).

The differential component from the current sources may distort or alter the differential signal from the driver 102, which may change the characteristics of the signal provided to the load 104. As a result, in the example of the load 104 being a speaker, the audible signal produced by the speaker 104 using the differential signal from the driver 102 may be distorted, changed, or otherwise altered in an undesired manner.

As a result, additional adjustments to the currents sourced or sunk by the current sources may be used to account for the differential component of the currents used to cancel the common mode signal from the protection and/or other circuitry.

In summary, then, in some examples a common mode signal may exist due to the design, nature, or characteristics of circuits connected to the system 100, and current sources may be used to control (e.g., decrease or increase) this common mode signal. However, those current sources may introduce a differential component due to resistor mismatch. As a result, the current sources may be configured to account for the differential component they themselves introduce by, for example, sinking or sourcing additional current corresponding to the differential component to cancel the differential component.

The driver 102 is coupled to the load 104, first resistor 106, and second resistor 108. The first resistor 106 is coupled (e.g., via the first bus 124a) to the first current source 114, the third current source 118, and the fifth current source 122, as well as the loop filter 124. The second resistor 108 is coupled (e.g., via the second bus 124b) to the second current source 116, the fourth current source 120, and the loop filter 124. The loop filter 124 is coupled to the VCMO 126. The VCMO 126 is coupled to the third current source 118 and fourth current source 120. The components listed above may also be coupled to other components.

The driver 102 is configured to provide input signals to the first resistor 106, load 104, and second resistor 108. The driver 102 may be, for example, an H-bridge or similar device. The driver 102 may provide a first input signal to the HPP node (e.g., to the first resistor 106), and may provide a second input signal to the HPN node (e.g., to the second resistor 108). The signals provided to the HPP and/or HPN nodes may be transmitted across the resistors 106, 108 to the busses 124a, 124b.

The load 104 may be an impedance (e.g., a resistance or reactance) representative of a device coupled to the driver 102 and being driven by the driver 102. In some examples, the load 104 may be omitted or may be optional.

The first resistor 106 may have a resistance and/or reactance, R1. The second resistor 106 may have a resistance and/or reactance, R2. In some examples, R1 and R2 may be equal or approximately equal, and in some examples, R1 and R2 may not be equal or approximately equal.

The first current source 114 is configured to source or sink current to or from the first bus 124a. The second current source 116 is configured to source or sink current to or from the second bus 124b. In some examples, the first current source 114 and second current source 116 source or sink the same amount of current. For example, if during a given cycle or half cycle, the first current source 114 sources ImA of current, then during the same cycle or half cycle or during the next cycle or next half cycle, the second current source 116 may source ImA of current as well. In various examples, the amount of current sourced or sunk by the first current source 114 and the second current source 116 may be constant throughout operation of the system 100. That is, the first current source 114 and second current source 116 may be configured to provide the same amount of current every time they source or sink current (e.g., if the first current source 114 sourced ImA of current during a first cycle, it will continue to source ImA of current for every following cycle during operation of the system 100). In some examples, the first current source 114 and the second current source 116 may represent the common mode signal from the protection circuit and/or other circuits connected to the system 100.

The third current source 118 is configured to source or sink current to or from the first bus 124a. The fourth current source 120 is configured to source or sink current to or from the second bus 124b. The third current source 118 and fourth current source 120 may be configured to source or sink the same amount of current when active (e.g., if the third current source 118 sinks ImA of current, the fourth current source 120 will also sink ImA of current on the same cycle or half cycle, or the next cycle or half cycle). The amount of current sourced or sunk by the third current source 118 and fourth current source 120 will be equal or approximately equal over time in some examples. In some examples, the third current source 118 and fourth current source 120 may be configured to source or sink an amount of current based on the current sourced or sunk by the first and second current sources 114, 116.

The amount of current sourced or sunk by the third current source 118 and/or fourth current source 120 may vary over time. For example, if during one cycle the third current source 118 sources ImA, during a later cycle the third current source 118 may sink 0.5 mA. In general, the amount of current sourced or sunk by the third and fourth current sources 118, 120 can depend on conditions in the rest of the system 100 or in devices to which the system 100 is connected or integrated.

For example, because the first and second current sources 114, 116 source or sink a constant amount of current, changes in ambient conditions may cause the driver 102 or other characteristics of the system 100 to change. For example, the output of the driver 102 may drift as ambient conditions change (e.g., the output of the driver 102 may increase or decrease due to ambient conditions), thus the current and/or voltage on the busses 124a, 124b may change, which in turn may cause the loop filter 124 output to change. To account for these changes due to ambient conditions, the third current source 118 and/or fourth current source 120 may be controlled to increase or decrease the amount of current sourced or sunk so that the inputs (e.g., voltage or currents on the first bus 124a and/or second bus 124b) to the loop filter 124 remain approximately constant or within a desired range of values.

The fifth current source 122 may be configured to source or sink additional current. In some examples, the fifth current source 122 may source or sink current related to inputs from the driver 102, as will be discussed later.

The loop filter 124 is configured to process the inputs (e.g., the voltage and/or current on the first bus 124a and/or second bus 124b). In some examples, the first input signal (e.g., on the first bus 124a) is provided to a first input of the loop filter 124, and the second input signal (e.g., on the second bus 124b) is provided to a separate second input of the loop filter 124. The loop filter 124 may provide a conditioned or processed signal based on the first input signal and/or the second input signal to the VCMO 126.

The VCMO 126 is configured to measure the output of the loop filter 124 and to adjust the behavior of the third and/or fourth current sources 118, 120.

The current sources 114, 116, 118, 120, 122 may each respectively include matching resistors for its inputs and/or outputs, and said resistors may be chopped. Matching resistors may be “birthday matched,” meaning that the resistors are selected from the same batch of resistors produced or manufactured at the same time. As a result, the resistors may closely match for a given current source. In some examples, one or more current sources may include resistors that have been matched and/or chopped to be closely matching. For example, the first and second current sources 114, 116 may be matched, and/or the third and fourth current sources 118, 120 may be matched, and so forth. Matching of the current sources 114, 116, 118, 120, 122 may result in minimized differential error (e.g., due to flicker), but may, in some examples, leave residual white noise from the transistors. The current sources 114, 116, 118, 120, 122 may be high precision (e.g., in comparison to current sources used in the measurement system of the auDAC block 112 and/or VCMO 126).

As mentioned above, the fifth current source 122 may be used to source or sink additional current. In some examples, the amount of current sourced or sunk by the fifth current source 122 may correspond to the differential current caused by one or more of the other current sources 114, 116, 118, 120. For example, as mentioned above, the current sources, when controlling the common mode signal due to the protective circuitry and/or other circuits connected to the system 100, may cause a differential signal to arise due to resistor mismatch of the first and second resistors 106, 108. This portion of the resistor mismatch may be unwanted and/or undesirable, and so the fifth current source 122 may source or sink an amount of current equal to or approximately equal to the unwanted differential signal, leaving behind only the differential signal produced by the driver 102.

In some examples, the auDAC block 112 may be split into two or more sections. In at least some examples, the auDAC block 112 includes a main area with a first plurality of bit-cells that supply differential current to the loop filter 124 input with a dynamic-element-matching network (DEM) optimized to minimize noise. In at least some examples, the auDAC block 112 further includes a common mode control area with a second plurality of bit-cells with a corresponding DEM optimized to minimize differential noise. In some examples, when driving the current sources of the auDAC block 112 (e.g., the third current source 118 and fourth current source 120), the auDAC block 112 (including its internal DEMs and DACs) may use the same bit-cells during each respective negative and positive pulse (e.g., each half-cycle).

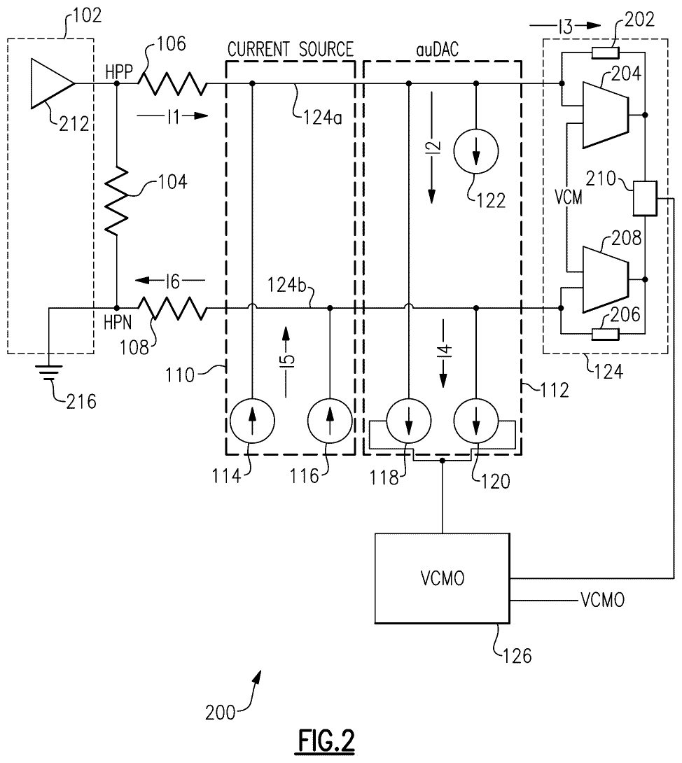

FIG. 2 illustrates a second system 200 (“system 200”) according to an example. The system 200 includes many of the elements of the first system 100 of FIG. 1, but adds additional elements to the driver 102 and the loop filter 202. The system 200 may be operating in a voltage driven (ZOR) mode of operation, as opposed to a current driven (HOR) mode of operation.

The driver includes an amplifier 212 coupled to the first resistor 106 and the load 104 (e.g., to the HPP node), and includes a ground node 216 coupled to the second resistor 108 and the load 104 (e.g., to the HPN node).

The loop filter 124 includes a first impedance 202, a first integrator 204, a second impedance 206, a second integrator 208, and a switch 210. The first impedance 202 is coupled to the first bus 124a and to the switch 210. The second impedance 206 is coupled to the second bus 124b and the switch 210. The first integrator 204 has a first input that is coupled to the first bus 124a and a second input that is coupled to a node providing the common mode voltage. The first integrator 204 has an output coupled to the switch 210. The second integrator 208 has a first input that is coupled to the second bus 124b and a second input that is coupled to a node providing the common mode voltage. The second integrator 208 has an output coupled to the switch 210. The switch 210 is further coupled to the VCMO 126.

The amplifier 212 is configured to provide an input signal (e.g., a voltage and/or current) to the HPP node. The amplifier 212 may provide an input signal that has been modified in some way (e.g., amplified or attenuated). The ground node 216 is configured to connect the HPN node to ground or to a reference voltage.

The first impedance 202 may be any type of impedance, for example, one or more capacitors, inductors, and/or resistors. The second impedance 206 may be any type of impedance, for example, one or more capacitors, inductors, and/or resistors.

The first integrator 204 may provide an output to the switch 210 based on the common mode voltage and an input (e.g., voltage and/or current) on the first bus 124a. The second integrator 208 may provide an output to the switch 210 based on the common mode voltage and an input (e.g., voltage and/or current) on the second bus 124b.

The switch 210 is configured to selectively connect one of the output of the first integrator 204 and the output of the second integrator 208 at a time to the VCMO 126. The state of the switch 210 may be based on a polarity of the system 100. For example, if the system 100 is providing and/or experiencing a pulse (e.g., is active) the switch 210 may provide one of the outputs (the output of the first integrator 204 or the output of the second integrator 208) to the VCMO 126, while if the system 100 is not providing and/or experiencing a pulse (e.g., is inactive), the switch 210 may provide the other of the outputs to the VCMO 126.

Various currents are labeled in FIG. 2. These currents include I1, I2, I3, I4, I5, and I6. I1 is a current that passes from the HPP node through the first resistor 106 to the first bus 124a. I2 is a current corresponding to the current being sunk or sourced by the fifth current source 122. I3 is a current from the input of the loop filter 124 to the output of the loop filter 124, and may, in some examples, be the current from the first bus 124a across the first impedance 202 to the switch 210. I4 is the current being sunk or sourced by the third or fourth current sources 118, 120. That is, 14 represents the current being sunk or sourced by one of the third current source 118 or fourth current source 120, such that the total current sunk or sourced by both the third and fourth current sources 118, 120 is equal to 2. I4. The current 15 is the current being sourced or sunk by the first or second current source 114, 116. That is, the total current being sourced or sunk by both the first and second current sources 114, 116 is equal to 2. I5. I6 is the current from the second bus 124b across the second resistor 108 to the HPN node.

I1 may be expressed by the equations:

$$I {1}_{a} = IDD - ICM \qquad ( 1 )$$

$$I {1}_{b} = - ICM \qquad ( 2 )$$

$$I {1}_{c} = \frac{{V}_{HPP}}{R 1} - ICM \qquad ( 3 )$$

where V_{HPP} is the voltage at the HPP node and R1 is the resistance of the first resistor 106. ICM may be equal to I5. IDD may be based on a high voltage and the resistance of the first resistor 106 (e.g., VDD may be the highest voltage in the system 200 and/or the output voltage of the amplifier 212). In some examples, I1ₐ may correspond to the value of I1 during an active state of the system 100 (e.g., when a pulse is present), I1_{b} may correspond to the value of I1 during an idle period (e.g., when the no pulse is present), and Ile may correspond to the value of I1 on average over time.

I2 may be expressed by the equation:

$$I 2 = \frac{{V}_{HPP}}{R 1} + IEHD \qquad ( 4 )$$

where IEHD is the portion of the current being sunk that corresponds to the unwanted differential component.

I3 may be expressed by the equations:

$$I {3}_{a} = IDD - \frac{{V}_{HPP}}{R 1} \qquad ( 5 )$$

$$I {3}_{b} = - \frac{{V}_{HPP}}{R 1} \qquad ( 6 )$$

where I3ₐ may correspond to a current when the system 100 is in an active state, and I3_{b} may correspond to a current when the system 100 is in an inactive state.

As mentioned above, I4 and I5 represent the currents being sourced or sunk by the respective current sources 114, 116, 118, 120 at any given time, and may be average values (e.g., over time, including active and inactive periods). I6 may equal I5 and may be an average value.

I3 does not have an average value, instead only having values for active and inactive states (e.g., when a pulse current is present and when no pulse current is present). In some examples, the average value of I3 should be zero over time, which corresponds to a steady state for the system 100 and corresponds to correction of any mismatches.

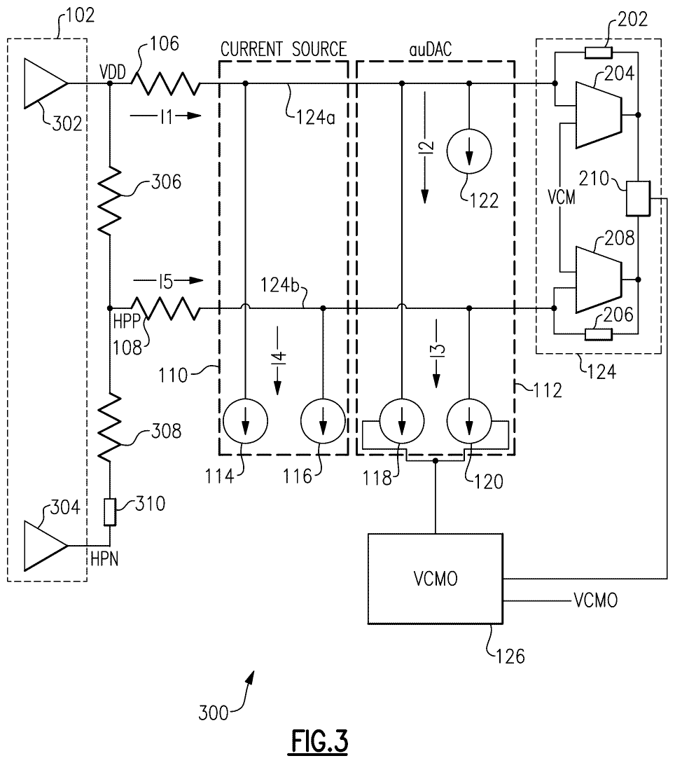

FIG. 3 illustrates a third system 300 (“system 300”) according to an example. The system 300 includes many of the elements of the first system 100 of FIG. 1 and the second system 200 of FIG. 2, but adds additional elements to the driver 102 and changes some of the elements present in the system 100 of FIG. 1. The system 300 may be operating in a HOR mode of operation.

The system 300 includes a first amplifier 302, a second amplifier 304, a sense resistor 306, a load resistance 308, and a load impedance 310. The system 300 also includes five currents, I1, I2, I3, I4, and I5. The HPP node and HPN nodes also occupy different positions compared to FIGS. 1 and 2.

The first amplifier 302 is coupled to the first resistor 106 and the sense resistor 306. The node where the first amplifier 302, first resistor 106, and sense resistor 306 are coupled together is labelled the VDD node. The sense resistor 306 is coupled to the second resistor 108 and the load resistance 308 at the HPP node. The load resistance 308 is further coupled to the load impedance 310 (in some examples, the load impedance 310 and load resistance 308 may be combined into a single impedance representing the total impedance of the load), and the load impedance 310 is coupled to the second amplifier 304 at the HPN node.

The voltage at the VDD node may be a highest voltage in the system 300 (e.g., VDD). The voltage at the HPP node may be VDD-VHP, where VHP is equal or based on the IDAC current and the input resistance of the first or second resistors 106, 108 (e.g., IDAC/RIN). The voltage at the HPN node may be equal to VDD during active operation (e.g., when a pulse is present), zero during inactive operation (e.g., when no pulse is present), and VDD−2·VHP on average.

With respect to the currents, I1 is the current from the VDD node across the first resistor 106 to the first bus 124a. I2 is the current sourced or sunk by the fifth current source 122. I3 is the current sourced or sunk by one of the third or fourth current sources 118, 120 (thus the total current sourced or sunk by the third and fourth current sources 118, 120 is 2·I3). I4 is the current sourced or sunk by the first and second current sources 114, 116 (thus the total current sourced or sunk by both the first and second current sources 114, 116 is equal to 2·I4). I5 is the current from the HPP node across the second resistor 108 to the second bus 124b. The currents may have the following values in some examples:

$$I 1 = IDAC + IDD - ICM \qquad ( 1 )$$

$$I 2 = IDAC + IEHD \qquad ( 2 )$$

$$I 4 = IDD - ICM \qquad ( 3 )$$

$$I 5 = IDD - ICM \qquad ( 4 )$$

Note that the value of 13 may be determined by the VCMO 126.

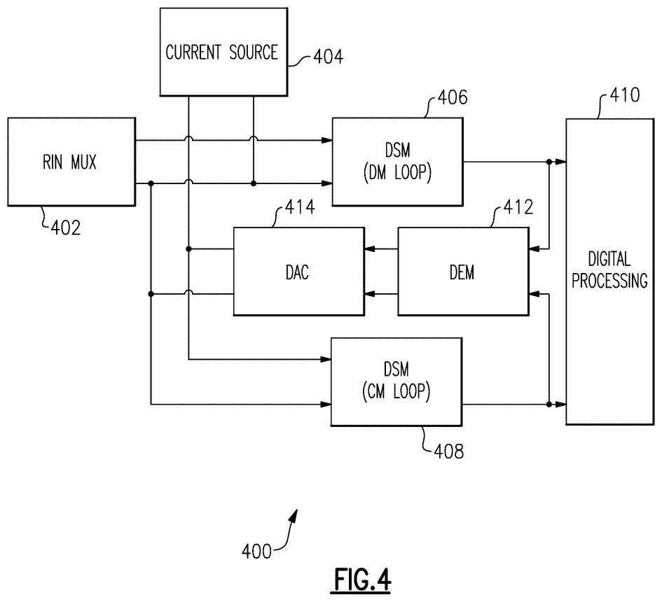

FIG. 4 illustrates a fourth system 400 (“system 400”) according to an example. The system 400 uses a closed loop to measure the inputs from the MUX 402, and then calculates an unwanted differential component precisely, so that the unwanted differential component may be removed.

The system 400 includes an input multiplexer 402 (“MUX 402”), a current source 404, a first DSM 406, a second DSM 408, a digital processing block 410, a DEM 412, and a DAC 414. The MUX 402 is coupled to the current source 404, first DSM 406, second DSM 408, and DAC 414. The current source 404 is coupled to the first DSM 406, second DSM 408, and DAC 414. The digital processing block 410 is coupled to the first DSM 406, second DSM 408, and DEM 412. The DEM 412 is coupled to the DAC 414. The DAC 414 is coupled to the first DSM 406 and second DSM 408.

The MUX 402 provides differential and common mode input signals to the DSMs 406, 408. In some examples, the MUX 402 may provide an HOR input signal, a positive driver input signal, and/or a negative driver input signal. The differential mode input is provided by the MUX 402 to the first DSM 406. The common mode input is provided by the MUX 402 to the second DSM 408. As an alternative framing, the first DSM 406 and second DSM 408 both receive the differential and common mode signals (because the MUX 402 provides only a single signal to both DSMs 406, 408), but the first DSM 406 is configured to measure the differential component of the signal, and the second DSM 408 is configured to measure the common mode component of the signal.

The current source 404 generates a current that is provided to the DSMs 406, 408. The current source 404 may provide a common mode current, and the common mode current produced by the current source 404 may cause a differential component to arise due to resistor mismatch in the MUX 402. In some examples, any differential component corresponding to the current source 404 may be considered an unwanted differential component.

The first DSM 406 is configured to measure the differential component of the signal it receives. This differential component may include the wanted differential components (e.g., corresponding to the output of the driver 102 of FIG. 1) and the unwanted differential components. In some examples, the order of the first DSM 406 may be higher than or equal to the order of the second DSM 408. For example, the first DSM 406 may be third order. In some examples, the first DSM 406 may therefore be a third order analog loop filter. The first DSM 406 may filter and/or measure components of the differential mode signal from the MUX 402 and may provide a multi-level (e.g., 3 level, 7 level, 10 level, and so forth) output, based on the differential mode signal, to the digital processing block 410 for quantization and to the DEM 412.

The second DSM 408 is configured to measure the common mode component of the signal it receives. The common mode component may include common mode components caused by connected circuitry (e.g., protective circuitry), and/or the current source 404 and/or the signal provided by the MUX 402 (if the MUX 402 provides a common mode signal distinct from the common mode signals discussed above). In some examples, the order of the second DSM 408 may be lower than or equal to the order of the first DSM 406. For example, the second DSM 408 may be second order. In some examples, the second DSM 408 may therefore be a second order analog loop filter. The second DSM 408 may filter and/or measure components of the common mode signal from the MUX 402 and may provide a multi-level (e.g., 3 level, 7 level, 10 level, and so forth) output, based on the common mode signal, to the digital processing block 410 for quantization and to the DEM 412.

In some examples, the output of the second DSM 408 may correspond to a measurement or be based on a measurement of the mismatch-induced error (e.g., the mismatch between the first and second resistors 106, 108 of FIG. 1). In some examples, the second DSM 408 may receive a feedback signal from the digital processing block 410, where the feedback signal is based on or a copy of the output signal from the second DSM 408 at an earlier time (e.g., during an earlier clock cycle).

The DEM 412 may receive the outputs of the first DSM 406 and second DSM 408 as inputs. Based on these inputs, the DEM 412 may provide one or more signals to the DAC 414 that determines the DAC 414 output. For example, the DEM 412 may provide a first signal to the DAC 414 for determining a first DAC 414 output, and the DEM 412 may provide a second signal to the DAC 414 for determining a second DAC 414 output. In some examples, the output the DEM 412 provides to the DAC 414 may be used to control the DAC 414 such that the DAC 414 provides an output signal that equals the input signal to the first and second DSMs 406, 408. That is, in some examples, the DEM 412 and DAC 414 may be configured to provide an output with a magnitude equal to and a polarity opposite that of the input signals. In some examples, the closed loop defined by the DEM 412, DAC 414, and DSMs 406, 408 may be configured to drive the output of the DAC 414 to a level where the input signal to the DSMs 406, 408 is zero. When the input is zero, this means the DSMs 406, 408 have precisely measured the various components of the input signals, thereby allowing the DEM 412 and DAC 414 to cancel the input signals. In this way, the error is driven toward zero as the DSMs 406, 408 approach the correct measurements. As the DSMs 406, 408 provide their measurements to the digital processing block 410, when the error is zero (or relatively close to zero), the digital processing block 410 may receive highly accurate indications of the common mode and differential components of the signals in the system 400.

The DAC 414 may use the output of the DEM 412 to provide one output to one of the differential input lines (or “bus”) and another output to the other of the differential input busses, thereby allowing the DAC 414 to reduce and/or minimize mismatches in the current and/or voltages on the input busses. The DAC 414 outputs may be analog signals.

The DEM 412 and DAC 414 may activate the same set or subset of cells during a given cycle or half-cycle when providing outputs based on the first signal and second signal. That is, the cells of the DAC 414 which are used to provide an output to one of the differentials inputs of the DSMs 406, 408 may also be used to provide the next output to the other of the differential inputs of the DSMs 406, 408 (e.g., in the next half-cycle, next cycle, at a later time, and so forth). In a subsequent cycle or half-cycle, different cells may be used such that over a number of cycles, any mismatch from one cell to another will appear as white noise or other background noise than may be filterable. By using the same cells for outputs to both differential inputs of the DSMs 406, 408, for example during both the active and inactive portions of a given cycle, the system 400 may ensure that the error, noise, or distortion associated with those cells is present in both signals provided by the DAC 414 to the differential inputs of the DSMs 406, 408. In some examples, the DAC 414 may have a first number of cells corresponding to the first DSM 406 and a second number of cells corresponding to the second DSM 408. For example, the first number of cells may be less than the second number of cells in some examples, or may be greater than the second number of cells in some examples. In some examples, the DAC 414 may have forty cells divided into six cells for the first DSM 416 and 34 cells for the second DSM 418.

The digital processing block 410 may receive input signals from the first DSM 406, the second DSM 408 that indicate the common mode and differential components of the signals measured by the DSMs 406, 408. The digital processing block 410 may determine the wanted differential components of the signals (e.g., the differential component corresponding to the output of the driver 102 of FIG. 1) based on the signals from the DSMs 406, 408. In particular, the digital processing block may subtract the common mode components out of the measurements and may determine the unwanted differential components based on the common mode components and stored values corresponding to the resistor mismatch. The digital processing block 410 may subtract out the unwanted differential components. The digital processing block 410 may determine the wanted differential components based on the result of removing the unwanted components from the total signal, and may provide a signal indicating the wanted differential components to another circuit, such as a programmable filter or the current sources of FIGS. 1-3. Those filters, current sources, or other processing hardware may then process out the unwanted components so that the unwanted components are not provided to the loop filter (e.g., the loop filter 124 of FIG. 1).

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various types of controllers may execute various operations discussed above. Using data stored in associated memory and/or storage, the controller also executes one or more instructions stored on one or more non-transitory computer-readable media, which the controller may include and/or be coupled to, that may result in manipulated data. In some examples, the controller may include one or more processors or other types of controllers. In one example, the controller is or includes at least one processor. In another example, the controller performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A system for equalizing errors in common mode inputs due to mismatches, the system comprising:
a driver configured to provide a first voltage to a first bus and a second voltage to a second bus;
a loop filter coupled to the first bus and to the second bus and configured to provide a feedback signal;
a first current source configured to source or sink a constant current from the first bus and the second bus;
a second current source configured to source or sink a variable current from the first bus and the second bus; and
a controller configured to
receive the feedback signal,
based on the feedback signal, determine a first value for the variable current, and
responsive to determining the first value, control the second current source to source or sink the variable current having the first value.

2. The system of claim 1 wherein the controller is further configured to
receive a second feedback signal responsive to controlling the second current source to source or sink the variable current having the first value,
determine a second value of the variable current responsive to receiving the second feedback signal, and
control the second current source to source or sink the variable current having the second value responsive to determining the second value.

3. The system of claim 1 further comprising a third current source configured to source or sink the constant current from one of the first bus or the second bus, wherein the first current source is configured to source or sink the constant current from the other of the first bus or the second bus.

4. The system of claim 1 further comprising a third current source configured to source or sink the variable current from one of the first bus or the second bus, wherein the second current source is configured to source or sink the variable current from the other of the first bus or the second bus.

5. The system of claim 1 further comprising a load coupled between the first bus and the second bus.

6. The system of claim 1 further comprising a first resistor coupled along the first bus between the driver and the loop filter.

7. The system of claim 6 further comprising a second resistor coupled along the second bus between the driver and the loop filter.

8. The system of claim 7 wherein an impedance of the first resistor is different than an impedance of the second resistor.

9. The system of claim 8 wherein the controller is configured to determine the first value of the variable current based on the difference between the impedance of the first resistor and the impedance of the second resistor.

10. The system of claim 9 wherein the controller determines the first value of the variable current to equalize the first voltage and the second voltage.

11. The system of claim 10 further comprising a third current source configured to source or sink the variable current from one of the first bus or the second bus, wherein the first current source and the second current source or sink the variable current from the other of the first bus or the second bus, and
the controller includes one or more cells configured to drive the second current source and the third current source, wherein the controller uses a same subset of cells to drive the second current source and the third current source during a first time and a subsequent second time.

12. The system of claim 11 wherein the controller drives the second current source during the first time and the third current source during the subsequent second time.

13. The system of claim 12 wherein the first time is a first half-cycle of a clock cycle and the subsequent second time is the second half-cycle of the clock cycle.

14. The system of claim 1 further comprising a third current source coupled to the first bus and configured to source or sink an additional current from the first bus.

15. The system of claim 1 wherein the driver is configured to operate in a current drive mode and a voltage drive mode.

16. The system of claim 1 wherein the loop filter includes a first integrator having a first input coupled to a common mode voltage and a second input coupled to the first bus, and wherein the loop filter includes a second integrator having a third input coupled to the common mode voltage and a fourth input coupled to the second bus.

17. The system of claim 16 further wherein the loop filter includes a switch coupled to an output of the loop filter, a first impedance coupled between the first bus and the switch, and a second impedance coupled between the second bus and the switch.

18. The system of claim 17 wherein the switch is configured to selectively couple the output of the loop filter to one of the first integrator or the second integrator at a given time.

19. A system for equalizing errors in common mode inputs due to mismatches, the system comprising:
a first bus configured to have a first voltage;
a second bus configured to have a second voltage;
a first delta-sigma modulator (DSM) having a first input coupled to the first bus, a second input coupled to the second bus, and an output coupled to an analog-to-digital converter (ADC);
a second DSM having a first input coupled to the first bus, a second input coupled to the second bus, a third input coupled to the ADC, and an output coupled to the ADC;
a dynamic-element-matching network (DEM) having a first input coupled to the ADC and a second input coupled to the ADC; and
a digital-to-analog converter (DAC) having a first input coupled to the DEM and a second input coupled to the DEM, and a first output coupled to the first bus and a second output coupled to the second bus.

20. The system of claim 19 wherein
the first DSM is configured to measure a first output signal of the DAC and a second output signal of the DAC and to provide a first feedback signal to the ADC;
the second DSM is configured to measure the first output signal and the second output signal and to provide a second feedback signal to the ADC;
the ADC is configured to receive the first feedback signal and the second feedback signal, and provide one or more control signals to the DEM;
the DEM is configured to receive the one or more control signals and to determine one or more bit-cells of the DAC to drive; and
the DAC is configured to output a first DAC output signal and a second DAC output signal based on the one or more bit-cells.
